(19) United States
(12) Patent Application Publication
(10) Pub. No.: US 2004/0208990 A1
(43) Pub. Date: Oct. 21, 2004

(54) Coating liquid for forming organic LED layer and method of manufacturing organic LED device using it

(75) Inventor: Yoshimasa Fujita, Kashihara-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/848,046

(22) Filed: May 19, 2004

Related U.S. Application Data
(62) Division of application No. 09/726,392, filed on Dec. 1, 2000.

(30) Foreign Application Priority Data
Dec. 9, 1999 (JP) 11(1999)-350267

(51) Int. Cl. B05D 5/06

(52) U.S. Cl. 427/162; 427/466

(57) ABSTRACT

A coating liquid for forming an organic LED layer which is used for forming an organic LED layer of an organic LED device by an inkjet method, comprising at least: a solvent and an organic material having a weight-average molecular weight less than 600,000.

### CROSS-REFERENCE TO RELATED APPLICATION

This application is related to Japanese application No. HEI 11(1999)-350267 filed on Dec. 9, 1999, whose priority is claimed under 35 USC § 119, the disclosure of which is incorporated by reference in its entirety.

### BACKGROUND OF THE INVENTION

1. Field of the Invention

The present invention relates to a coating liquid for forming an organic LED layer and a method of manufacturing an organic LED device using it. More specifically, the invention relates to a coating liquid for forming an organic LED layer capable of continuously and stably preparing organic LED layers while preventing the occurrence of clogging in an inkjet head in the case of forming organic LED layers in an organic LED device by an inkjet method and also to a method of manufacturing an organic LED device using the coating liquid.

2. Description of Related Art

Hitherto, for manufacturing an organic LED layer (for example, an organic light-emitting layer) in an organic LED device using an organic material, a spin coating method has been used. However, by the method, coloring of the organic LED layer by patterning has been very difficult.

However, recently, as one of the solving methods, a method of forming an organic LED layer by patterning using an inkjet system has been proposed (Japanese Unexamined Patent Publication No. HEI 10(1998)-12377, and Appl. Phys. Lett., 72, 9519, 1998).

However, in the case of forming the organic LED layer using the inkjet method, there is a problem that a coating liquid for forming the organic LED layer is liable to cause clogging of the head of inkjet, whereby it is difficult to continuously and stably forming the organic LED layer.

### SUMMARY OF THE INVENTION

As the result of earnestly making investigations in view of these circumstances, the present inventors have unexpectedly found that the cause of clogging of the head of inkjet is closely connected with the molecular weight of an organic materials which has not hitherto been taken notice of in the formation of organic LED layers, and have accomplished the present invention.

Thus, according to the invention, there is provided a coating liquid for forming an organic LED layer which is used for forming an organic LED layer of an organic LED device by an inkjet method, comprising at least: a solvent and an organic material having a weight-average molecular weight less than 600,000.

Furthermore, according to the invention, there is provided a method of manufacturing an organic LED device comprising the step of forming at least one layer of a single-layered or multi-layered organic LED layer of an organic LED device by an inkjet method using the above-described coating liquid for forming an organic layer.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic cross sectional view showing an embodiment of the organic LED device of the invention,

FIG. 2 is a schematic partial plan view illustrating the arrangement of organic light-emitting layers of an embodiment of the organic LED display of the invention,

FIG. 3A to 3D are schematic partial plane views of the arrangements of organic light-emitting layers of the embodiments of the organic LED display of the invention,

FIG. 4 is a schematic partial see-through view of an embodiment of the organic LED display of the invention,

FIG. 5 is a schematic partial see-through view of other embodiment of the organic LED display of the invention,

FIG. 6 is a schematic partial see-through view of another embodiment of the organic LED display of the invention,

FIG. 7 is a schematic view showing an embodiment of the formation steps of the organic LED layer of the invention,

FIG. 8 is a schematic view showing a discharging method of ink in the invention, and

FIG. 9 is a schematic view showing another embodiment of the discharging method of ink in the invention.

### DESCRIPTION OF THE PREFERRED EMBODIMENTS

Then the preferred embodiments of the invention are described in detail.

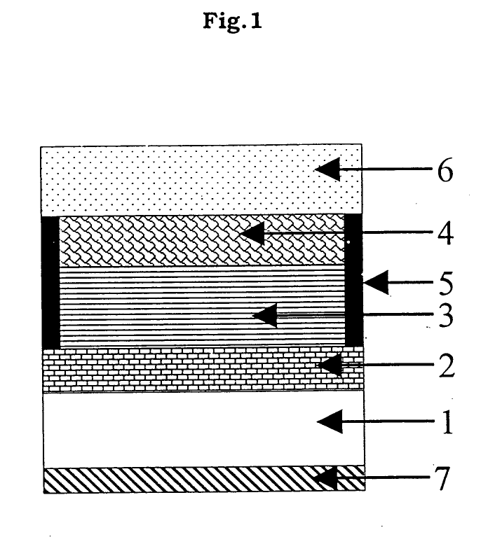

An organic LED device comprises at least a 1st electrode, an organic LED layer, and a 2nd electrode. In this case, the organic LED device may be formed on a substrate as shown in FIG. 1. In addition, in FIG. 1, the numeral 1 shows a substrate, 2 shows the 1st electrode, 3 shows the organic LED layer, and 4 shows the 2nd electrode.

The coating liquid of the invention is used for the formation of the organic LED layer 3 in the construction of the organic LED device of FIG. 1.

The organic LED layer has at least one organic light-emitting layer. Practically, there are a single layer structure of the organic light-emitting layer and a multilayer structure of a charge transport layer and the organic light-emitting layer. Furthermore, each of the charge transport layer and the organic light-emitting layer may be a multilayer structure.

The coating liquid of the invention is used for forming at least one layer of the layers constituting the above-described organic LED layer by an inkjet method.

The coating liquid for forming the organic LED layer of the invention can be divided into a coating liquid for forming the organic light-emitting layer and a coating liquid for forming the charge transport layer.

In this case, the coating liquid for forming the organic light-emitting layer corresponds to a coating liquid obtained by dissolving or dispersing, as an organic material, a known high-molecular light-emitting material for forming an organic LED layer, a precursor of a known high-molecular light-emitting material for forming an organic LED layer or a known low-molecular light-emitting material for forming an organic LED layer and a known high-molecular material in a solvent.

On the other hand, the coating liquid for forming the charge transfer layer corresponds to a coating liquid obtained by dissolving or dispersing a known high-molecular charge transport material for forming an organic LED layer and/or an organic photoconductor as an organic material, the precursor thereof or an organic material such as a known low-molecular charge transport material, etc., for forming the organic LED layer and/or the organic photoconductor, and a known high-molecular material in a solvent.

The weight average molecular weight of the above-described organic materials (the high-molecular light-emitting material and the precursor thereof, the low-molecular light-emitting material, the high-molecular charge transport material and the precursor thereof, the low-molecular charge transport material, and the high-molecular material) is less than 600,000. For obtaining the viscosity of the coating liquid suitable for forming the film thickness of not thicker than 200 nm as the organic LED layer and for discharging from the inkjet head, the weight average molecular weight of the organic materials is more preferably from 100,000 to 20,000. By using the organic materials having such a specific weight average molecular weight, the occurrence of clogging of the head caused by clogging the organic materials in the head and by the deposition of the solutes (organic materials, additives, etc.) in the head by drying can be prevented. Thereby, the organic LED device can be continuously manufactured.

As the organic materials which can be used in the invention, there is no particular restriction on the kind of the organic materials if the weight average molecular weight thereof is not more than 600,000, and the organic materials known in the field of the art can be used. Practical examples of the organic materials which can be used in the invention are shown below.

As the organic materials in the coating liquid for forming organic light-emitting layer, there are the high-molecular light-emitting material, the precursor thereof, the low-molecular light-emitting material, the high molecular material, etc.

The high-molecular light-emitting material includes, for example, poly(2-decyloxy-1,4-phenylene) (DO-PPP), poly{2,5-bis[2-(N,N,N-triethylammonium)ethoxy]-1,4-phenylene-ortho-1,4-phenylene}dibromide (PPP-NEt₃⁺), poly[2-(2′-ethylhexyloxy)-5-methoxy-1,4-phenylenevinylene] (MEH-PPV), poly[5-methoxy-(2-propanoxysulfonide)-1,4-phenylenevinylene] (MPS-PPV), poly[2,5-bis(hexyloxy)-1,4-phenylene-(1-cyanovinylene)] (CN-PPV), poly[2-(2′-ethylhexyloxy)-5-methoxy-1,4-phenylenevinylene-(1-cyanovinylene)] (MEH-CN-PPV), poly(9,9-di-n-octylfluorene) (PF), poly(benzothiazolefluorene) (PBF), poly-(naphthylfluorene) (PNF), poly(bithiophenylenefluorene) (PTF), etc.

The precursor of the high-molecular light-emitting material includes, for example, a poly(p-phenylene) precursor (Pre-PPP), a poly(p-phenylenevinylene) precursor (Pre-PPV) and poly(p-naphthalenevinylene) precursor (Pre-PNV).

The low-molecular light-emitting material includes, for example, tetraphenylbutadiene (TPB), coumarin, Nile Red, and an oxadiazole derivative.

The high molecular material includes, for example, polycarbonate (PC), polymethyl methacrylate (PMMA) and polyvinylcarbazole (PVCz).

Also, to the coating liquid for forming the organic light-emitting layer may be added, if necessary, additive such as a pH-controlling agent, a viscosity-controlling agent, a permeation-accelerating agent, a leveling agent, etc.; charge transport materials such as a known hole transport material, an electron transport material, etc., for the organic LED layer or the organic photoconductor; and a dopant such as an acceptor, a donor, etc.

The hole transport material includes, for example, N,N′-bis-(3-methylphenyl)-N,N′-bis-(phenyl)-benzidine (TPD), and N,N′-bis-(3-methylphenyl)-N,N′-bis-(phenyl)-benzidine (NPD).

The electron transport material includes, for example, 3-(4-biphenylyl)-4-phenylene-5-t-butylphenyl-1,2,4-triazole (TAZ) and tris(8-hydroxynate)aluminum (Alq₃).

As the organic materials in the coating liquid for forming the charge transport layer, there are the high-molecular charge transport material, the precursor thereof, the low-molecular charge transport material, the known high-molecular material, etc.

The high-molecular charge transport material includes, for example, polyaniline (PANI), 3,4-polyethylenedioxythiophene (PEDT), polystyrene sulfonate (PSS), PVCz, Poly-TPD and poly(oxadiazole)derivative (Poly-OXZ).

The precursor of the high-molecular charge transport material includes, for example, Pre-PPV and Pre-PNV.

The low-molecular charge transport material includes, for example, TPD, NPD and an oxadiazole derivative.

The high-molecular material includes, for example, PC, PMMA and PVCz.

Also, if necessary, to the coating liquid for forming the charge transport layer may be added additives such as the pH-controlling agent, the viscosity-controlling agent, the permeation accelerating agent, the leveling agent, etc.; and the dopant such as the acceptor, the donor, etc.

Also, as a solvent for constituting the coating liquids for forming the organic light-emitting layer and the charge transport layer, a solvent which has hitherto been used can be used. As the examples of the solvent, there are water, methanol, toluene, xylene, THF, and solvents having a vapor pressure at a temperature of at least 20° C. of not higher than 10 mm Hg. These solvents may be used singly or as a combination of them.

Examples of the solvents having a vapor pressure at a temperature of at least 20° C. of not higher than 10 mm Hg include polyhydric alcohols and the derivatives thereof, such as ethylene glycol, propylene glycol, triethylene glycol, ethylene glycol monomethyl ether, ethylene glycol monoethyl ether, triethylene glycol monomethyl ether, triethylene glycol monoethyl ether, glycerin, etc.; amide compounds such as formamide, N-methyl-2-pyrrolidone, etc.; aliphatic hydrocarbons and the derivatives thereof, such as nonane, decane, trichloropropane, etc.; and benzene derivatives such as o-dichlorobenzene, etc., although the invention is not limited to these solvents. In these solvents, ethylene glycol, N-methyl-2-pyrrolidone, o-dichlorobenzene, and trichloropropane are preferred.

Also, the mixing ratio of the organic materials and the solvent in the above-described coating liquid is preferably controlled such that the viscosity of the coating liquid becomes 62 mPa·s or lower at 20° C., is more preferably controlled such that the viscosity is 10 mPa·s or lower, and is particularly preferably controlled such that the viscosity becomes from 2 to 6 mPa·s.

Furthermore, it is preferred to control the kinds and the ratio of the organic materials and the solvent in the coating liquid such that the surface tension of the coating liquid becomes at least 40 dynes/cm to the surface to be coated. The more preferred surface tension is from 40 to 70 dynes/cm.

Then, the method of forming the organic LED device of the invention is explained. In addition, in the organic LED layer, if at least one layer is formed by the method of the invention, other layer(s) may be prepared by the method of the invention or may be prepared by other organic thin-film forming method of prior art (for example, a dry process such as a vacuum vapor deposition method or a wet process such as a dip coating method, a spin coating method, etc.).

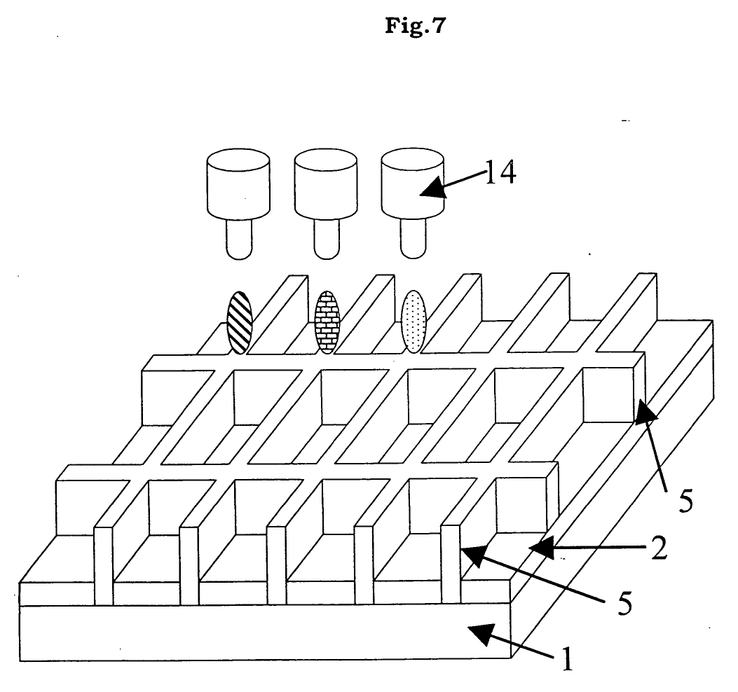

Then, the formation method of the organic LED layer (for example, the organic light-emitting layer and the charge transport layer) by the invention is explained. As shown in FIG. 7, the organic light-emitting layer can be formed on the 1st electrode or the charge transport layer by discharging the coating liquid for forming the organic light-emitting layer to the definite positions by the inkjet method. Also, the charge transport layer can be formed on the 1st electrode, the charge transport layer, or the organic light-emitting layer by discharging the coating liquid for forming the charge transport layer to the definite positions by the inkjet method.

Furthermore, when the prevention of overlapping and mixing of the organic light-emitting layers of each pixel and the uniformity of the film thickness distribution are taken into consideration, it is preferred that as shown in, for example, FIG. 1, a partition 5 is formed between the pixels. The partition may be a single layer structure or a multilayer structure. Also, it is preferred that the material of the partition is insoluble or slightly soluble in the coating liquid for the organic LED in the present invention. Also, it is more preferred that a material for a black matrix is used for the purpose of increasing the expressing dignity as a display.

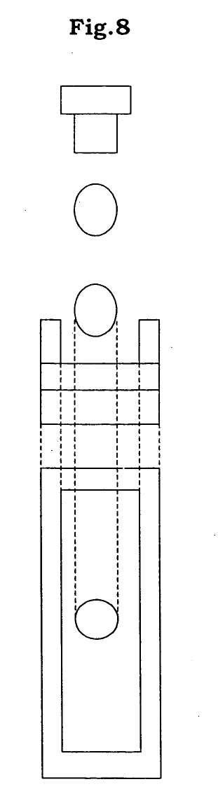

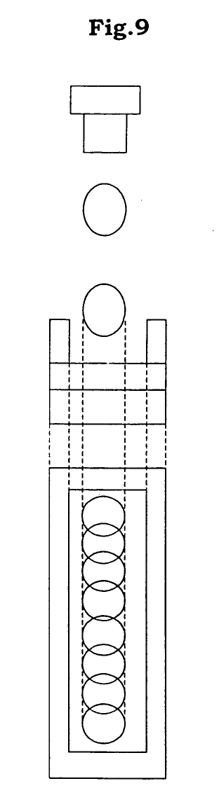

Also, in the case of forming one pixel, one liquid only may be discharged in the pixel partitioned by the partition, many liquids may be discharged to a same place as shown in FIG. 8, or may be discharged to different places as shown in FIG. 9. Also, as nozzles for discharging coating liquids, it is preferred to use each different nozzle for each light-emitting color. Furthermore, one nozzle may be used for a same coating liquid, but from the view point of the manufacturing speed, the use of plural nozzles is preferred. Also, as the discharging method of the coating liquid, according to the arrangement of the light-emitting colors of the organic LED device prepared, it may be a continuous type or an on-demand type. A piezo type is more preferred for preventing the occurrence of the denaturation of the organic materials contained in the coating liquid due to heat.

After coating the coating liquid, to completely remove the solvent, it is preferred to dry by heating. Also, the heat-drying may be carried out in air but from the view point of preventing the deterioration of the organic materials, it is preferred to carry out the heat-drying in an inert gas. Also, the heat-drying may be carried out under the atmospheric pressure but from the view point of preventing the deterioration of the organic materials, it is preferred to carry out under a reduced pressure.

As other construction of the organic LED device than the above-described organic LED layer, there are, for example, following modified embodiments.

First, from the view point of improving the contrast, it is preferred that a polarizing plate 7 is formed on the outer side of the substrate 1 as shown in FIG. 1. Also, from the view point of improving the reliability, it is preferred to form a sealing film or sealing substrate 6 on the 2nd electrode 4 of the organic LED device.

As the 1st electrode and the 2nd electrode holding the above-described organic LED layer between them, in the above-described organic LED device, when the substrate and the 1st electrode are transparent, the emitted light from the organic LED layer is emitted from the substrate side, and thus to increase the light-emitting efficiency, it is preferred that the 2nd electrode is a reflecting electrode or the 2nd electrode has a reflecting film thereon. On the contrary, the 2nd electrode is made of a transparent electrode and the emitted light from the organic LED layer can be emitted from the 2nd electrode side. In this case, it is preferred that the 1st electrode is a reflecting electrode or the substrate is a reflecting substrate, or a reflecting film is formed between the 1st electrode and the substrate.

In this case, as the substrate, a quartz substrate, a glass substrate, or a plastic substrate can be used but the invention is not limited to these substrates.

As the material of the transparent electrode, CuI, ITO, SnO₂, ZnO, etc., can be used. As the material of the reflecting electrode, metals such as aluminum, calcium, etc.; alloys such as a magnesium-silver alloy, a lithium-aluminum alloy, etc.; laminated films of metals such as magnesium/silver, etc.; and laminated films of insulators and metals, such as lithium fluoride/aluminum, etc., can be used. However, the invention is not limited to these materials.

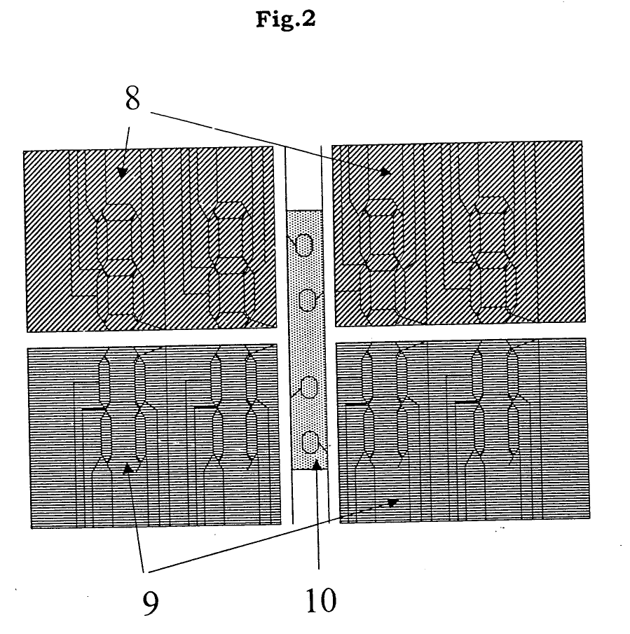

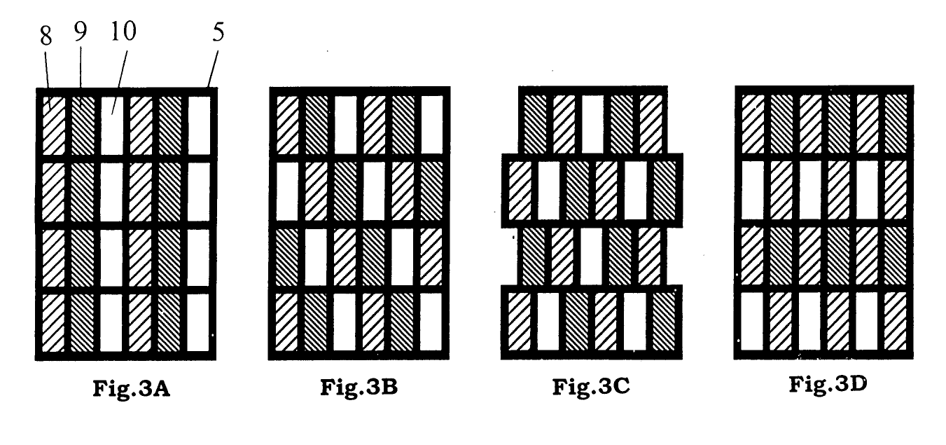

Then, by integrating plural organic LED devices described above, an organic LED display is constructed. In this case, the arrangement of the organic light-emitting layers of the organic LED display is explained. The organic LED display may be constituted from areas wherein each portion of the display has a different light-emitting color as shown in FIG. 2. Also, when the organic LED layers have the structure of being arranged in a matrix form as shown in FIG. 3A, each of the organic LED layers may be preferably constituted from a red (R) light-emitting pixel 1, a green (G) light-emitting pixel 2, and a blue (B) light-emitting pixel 3. Furthermore, in place of the stripe arrangement, the arrangement may be as shown in FIG. 3B or FIG. 3C. Also, as shown in FIG. 3D, the ratio of the red (R) light-emitting pixel 1, the green (g) light-emitting pixel, and the blue (B) light-emitting pixel may be not always the ratio of 1:1:1. Also, the light-emitting areas of the pixels may be same or different. In addition, the arrangements of FIG. 3B, FIG. 3C, and FIG. 3D are called a mosaic arrangement, a delta arrangement, and a square arrangement, respectively.

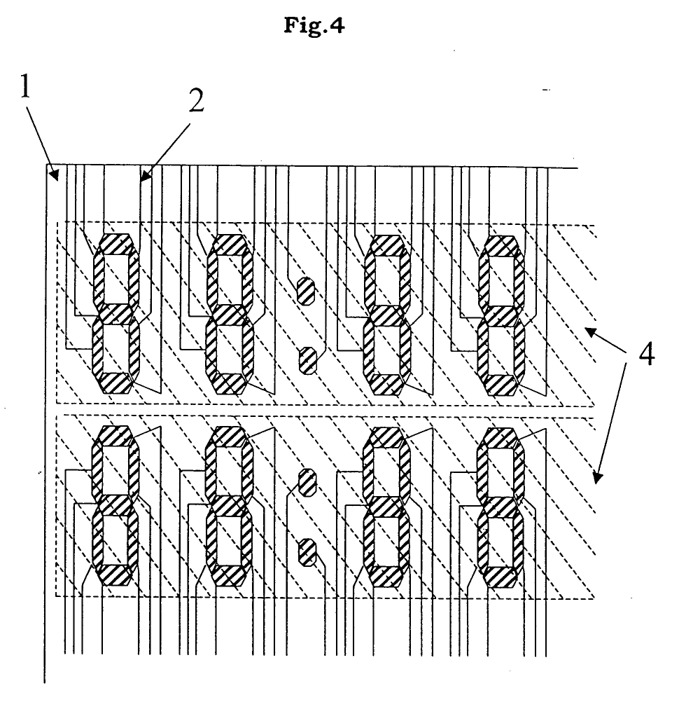

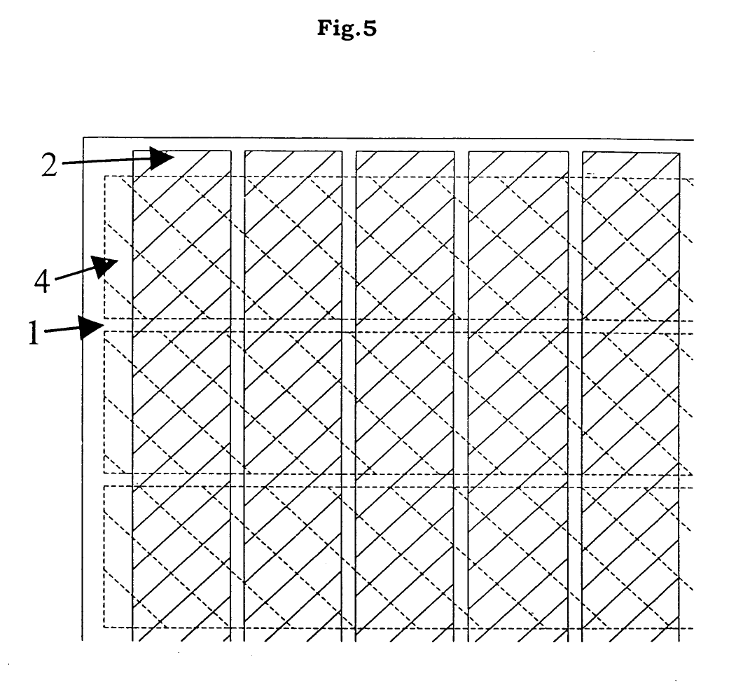

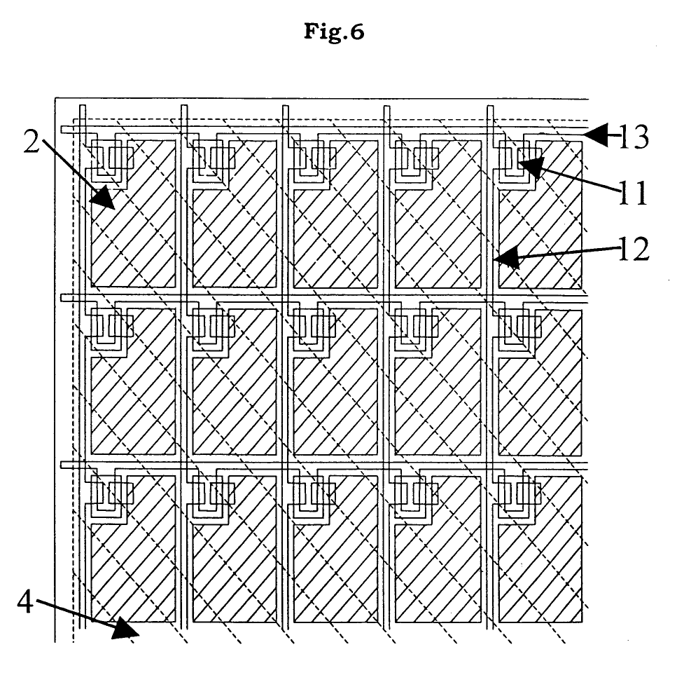

Then, the connection method of between the 1st electrodes and between the 2nd electrodes corresponding to each pixel is explained. In the organic LED display, as shown in FIG. 4, the 1st electrode or the 2nd electrode may be an independent electrode to each pixel. Also, as shown in FIG. 5, the 1st electrode and the 2nd electrode corresponding to the above-described organic LED layer may be constructed such that they become stripe-form electrodes crossing at a right angle each other on a common substrate. Furthermore, as shown in FIG. 6, the 1st electrode or the 2nd electrode may be constructed such that the −electrode is connected to a common electrode (source bus line, gate bus line) via a thin-film transistor (TFT).

In this case, the TFT corresponding to one pixel may be one or may be plural (see, for example, Japanese Unexamined Patent Publication No.HEI 10(1998)-234683). Also, the 1st electrode or the 2nd electrode may be connected to a common electrode via an MIM diode (see, for example, Japanese Unexamined Patent Publication No.HEI 10(1998)-268798).

### EXAMPLE

Then, the present invention is described more practically by the following examples.

### Preparation of Coating Liquid for Forming Organic LED Layer

[Preparation of Coating Liquid for Forming Organic Light-emitting Layer]

### Example 1

By dissolving 0.01 g of the precursor of poly(p-phenylenevinylene) (hereinafter, is referred to as Pre-PPV) shown by following structural formula (1) having a weight average molecular weight of 20,000 in methanol at a concentration of 0.1% by weight, a coating liquid for forming an organic light-emitting layer was prepared.

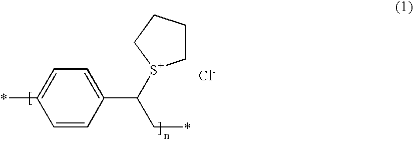

### Example 2

By following the same procedure as Example 1 except that 0.01 g of Pre-PPV having a weight average molecular weight of 60,000 was used in place of the Pre-PPV having the weight average molecular weight of 20,000, a coating liquid was prepared.

### Example 3

By following the same procedure as Example 1 except that 0.01 g of Pre-PPV having a weight average molecular weight of 100,000 was used in place of the Pre-PPV having the weight average molecular weight of 20,000, a coating liquid was prepared.

### Example 4

By following the same procedure as Example 1 except that 0.01 g of Pre-PPV having a weight average molecular weight of 400,000 was used in place of the Pre-PPV having the weight average molecular weight of 20,000 and was dissolved in methanol at a concentration of 0.025% by weight, a coating liquid was prepared.

### Comparative Example 1

By following the same procedure as Example 1 except that 0.01 g of Pre-PPV having a weight average molecular weight of 600,000 was used in place of the Pre-PPV having the weight average molecular weight of 20,000 and was dissolved in methanol at a concentration of 0.015% by weight, a coating liquid was prepared.

### Example 5

By following the same procedure as Example 3 except that 0.1 g of Pre-PPV was dissolved in methanol at a concentration of 1.0% by weight, a coating liquid was prepared.

### Example 6

By following the same procedure as Example 3 except that 0.001 g of the Pre-PPV was dissolved in methanol at a concentration of 0.01% by weight, a coating liquid was prepared.

### Example 7

By following the same procedure as Example 2 except that pure water was used as the solvent in place of methanol, a coating liquid was prepared.

### Example 8

By following the same procedure as Example 2 except that ethylene glycol was used as the solvent in place of methanol, a coating liquid was prepared.

### Example 9

By following the same procedure as Example 2 except that a mixed solvent of pure water, ethylene glycol and methanol at 85:10:5 by weight ratio was used as the solvent in place of methanol, a coating liquid was prepared.

### Example 10

By dissolving 0.01 g of poly{2,5-bis[2-(N,N,N-triethylammonium)ethoxy]-1,4-phenylene-ortho-1,4-phenylene}dibromide (hereinafter, is referred to as PPP-NEt₃⁺) shown by following structural formula (2) having a weight average molecular weight of 20,000 in pure water at a concentration of 0.1% by weight, a coating liquid for forming an organic light-emitting layer was prepared.

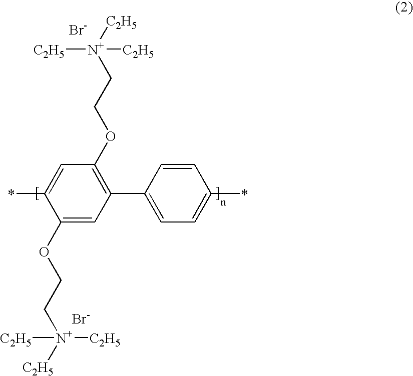

### Example 11

By following the same procedure as Example 10 except that 0.01 g of PPP-NEt₃⁺ having a weight average molecular weight of 60,000 was used in place of the PPP-NEt₃⁺ having the weight average molecular weight of 20,000, a coating liquid was prepared.

### Example 12

By following the same procedure as Example 10 except that 0.01 g of PPP-NEt₃⁺ having a weight average molecular weight of 100,000 was used in place of the PPP-NEt₃⁺ having the weight average molecular weight of 20,000, a coating liquid was prepared.

### Example 13

By following the same procedure as Example 10 except that 0.01 g of PPP-NEt₃⁺ having a weight average molecular weight of 400,000 was used in place of the PPP-NEt₃⁺ having the weight average molecular weight of 20,000 and dissolved in pure water at a concentration of 0.025% by weight, a coating liquid was prepared.

### Comparative Example 2

By following the same procedure as Example 10 except that 0.01 g of PPP-NEt₃⁺ having a weight average molecular weight of 600,000 was used in place of the PPP-NEt₃⁺ having the weight average molecular weight of 20,000 and dissolved in pure water at a concentration of 0.015% by weight, a coating liquid was prepared.

### Example 14

By following the same procedure as Example 11 except that 0.1 g of the PPP-NEt₃⁺ was dissolved in pure water at a concentration of 1.0% by weight, a coating liquid was prepared.

### Example 15

By following the same procedure as Example 11 except that 0.001 g of the PPP-NEt₃⁺ was dissolved in pure water at a concentration of 0.01% by weight, a coating liquid was prepared.

### Example 16

By following the same procedure as Example 11 except that ethylene glycol was used as the solvent in place of pure water, a coating liquid was prepared.

### Example 17

By following the same procedure as Example 11 except that N-methyl-2-pyrrolidone was used as the solvent in place of pure water, a coating liquid was prepared.

### Example 18

By following the same procedure as Example 10 except that a mixed solvent of pure water, ethylene glycol, and methanol at 70:20:10 by weight ratio was used as the solvent in place of pure water, a coating liquid was prepared.

### Example 19

By dissolving 0.01 g of poly[2-(2′-ethylhexyloxy)-5-methoxy-1,4-phenylenevinylene-(1-cyanovinylene)] (herein-after, is referred to as MEH-CH-PPV) shown by following structural formula (3) having a weight average molecular weight of 20,000 in toluene at a concentration of 0.1% by weight, a coating liquid for forming an organic light-emitting layer was prepared.

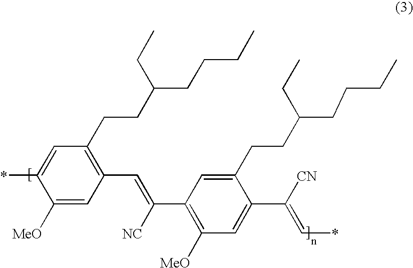

### Example 20

By following the same procedure as Example 19 except that 0.01 g of MEH-CH-PPV having a weight average molecular weight of 60,000 was used in place of the MEH-CH-PPV having a weight average molecular weight of 20,000, a coating liquid was prepared.

### Example 21

By following the same procedure as Example 19 except that 0.01 g of MEH-CH-PPV having a weight average molecular weight of 100,000 was used in place of the MEH-CH-PPV having a weight average molecular weight of 20,000, a coating liquid was prepared.

### Example 22

By following the same procedure as Example 19 except that 0.01 g of MEH-CH-PPV having a weight average molecular weight of 400,000 was used in place of the MEH-CH-PPV having a weight average molecular weight of 20,000 and dissolved in toluene at a concentration of 0.025% by weight, a coating liquid was prepared.

### Comparative Example 3

By following the same procedure as Example 19 except that 0.01 g of MEH-CH-PPV having a weight average molecular weight of 600,000 was used in place of the MEH-CH-PPV having a weight average molecular weight of 20,000 and dissolved in toluene at a concentration of 0.015% by weight, a coating liquid was prepared.

### Example 23

By following the same procedure as Example 20 except that 0.1 g of MEH-CH-PPV was dissolved in toluene at a concentration of 1.0% by weight, a coating liquid was prepared.

### Example 24

By following the same procedure as Example 20 except that 0.001 g of MEH-CH-PPV was dissolved in toluene at a concentration of 0.01% by weight, a coating liquid was prepared.

### Example 25

By following the same procedure as Example 20 except that o-dichlorobenzene was used as the solvent in place of toluene, a coating liquid was prepared.

### Example 26

By following the same procedure as Example 20 except that trichloropropane was used as the solvent in place of toluene, a coating liquid was prepared.

### Example 27

By following the same procedure as Example 21 except that a mixed solvent of o-dichlorobenzene and toluene at 60:40 by weight ratio was used as the solvent in place of toluene, a coating liquid was prepared.

[Preparation of Coating Liquid for Forming Charge Transport Layer]

### Example 28

By dissolving 0.01 g of 3,4-polyethylenedioxythiophene (hereinafter, is refereed to as PEDT) shown by following structural formula (4) having a weight average molecular weight of 60,000 in a mixed solvent of pure water, ethylene glycol, and methanol of 70:20:10 by weight ratio at a concentration of 0.1% by weight, a coating liquid for forming a charge transport layer was prepared.

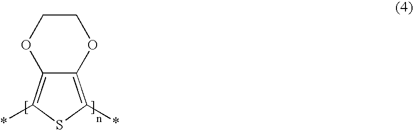

In addition, each of the materials described above was synthesized by a known method. Also, the control of the weight average molecular weight of each of the materials was carried out by changing the reaction condition (particularly, by controlling the amount of each of the polymerization initiators used at forming a high molecule from each monomer) and classifying synthesized high molecular materials to the material having the specific molecular weight using GPC or a dialysis tube.

### Evaluation 1: Continuous Discharging Evaluation

Each of the coating liquids for organic LED obtained in the examples and the comparative examples described above was filled in an ink tank of an inkjet printing apparatus, the coating liquid for forming organic LED layer was continuously discharged from the head nozzle, and the extent of discharging was determined.

The evaluation standard is as follows.

A: The case of not causing discharge failure 100 hours or longer.

B: The case of causing discharge failure before 100 hours.

C: The case of causing discharge failure before 10 hours.

D: The case of causing discharge failure before 1 hour.

E: The case of causing discharge failure from the first.

+: The case that after cleaning 10 times the head nozzle caused discharge failure, the coating liquid for forming organic LED layer was filled again, and when the coating liquid was discharged from the head nozzle, the coated liquid was discharged.

−: The case that after cleaning 10 times the head nozzle caused discharge failure, the coating liquid for forming organic LED layer was filled again, and when the coating liquid was discharged from the head nozzle, the coating liquid was not discharged.

### Evaluation 2: Cleaning Evaluation

About the case caused the discharge failure in the above-described evaluation 1, cleaning was carried out, the coating liquid was discharged again, and the extent of discharging was determined. In this case, cleaning is that by filling the solvent only used for preparing the coating liquid for forming organic LED layer in the head and discharging, unnecessary matters in the head are removed.

The evaluation standard is as follows.

O: The case that by the cleaning, the coating liquid for forming organic LED layer was discharged.

x: The case that even by carrying out the cleaning, the coating liquid for forming organic LED layer was not discharged.

TABLE 1

| | Materials | | | | | | |
|---|---|---|---|---|---|---|---|
| | Solvent | | | Weight average | Viscosity of | | |
| | | Mixing | Vapor | molec. weight | coating | | |
| | Solvent | ratio | pressure | of organic | liquid | Evaluation | |
| | name | (%) | (mm Hg) | material | (mPa · s) | 1 | 2 |
| E1 | Methanol | 100 | 97.3 | 20,000 | 1.32 | C | O |
| E2 | Methanol | 100 | 97.3 | 60,000 | 2.47 | C | O |
| E3 | Methanol | 100 | 97.3 | 100,000 | 4.25 | C | O |
| E4 | Methanol | 100 | 97.3 | 400,000 | 5.96 | C | O |
| CE1 | Methanol | 100 | 97.3 | 600,000 | 4.82 | E | x |
| E5 | Methanol | 100 | 97.3 | 100,000 | 22.1 | D | O |
| E6 | Methanol | 100 | 97.3 | 100,000 | 1.49 | C | O |
| E7 | Pure water | 100 | 17.5 | 60,000 | 3.01 | B | O |
| E8 | E. G. | 100 | 0.083 | 60,000 | 61.8 | D | x |
| E9 | pure water | 85 | 17.5 | 60,000 | 3.87 | A | — |
| | E. G. | 10 | 0.083 | | | | |
| | methanol | 5 | 97.3 | | | | |
| E10 | pure water | 100 | 17.5 | 20,000 | 1.48 | B | O |
| E11 | pure water | 100 | 17.5 | 60,000 | 2.56 | B | O |
| E12 | pure water | 100 | 17.5 | 100,000 | 4.13 | B | O |
| E13 | pure water | 100 | 17.5 | 400,000 | 3.78 | B | O |
| CE2 | pure water | 100 | 17.5 | 600,000 | 4.78 | E | x |
| E14 | pure water | 100 | 17.5 | 60,000 | 14.3 | D | O |
| E15 | pure water | 100 | 17.5 | 60,000 | 1.56 | B | O |
| E16 | E. G. | 100 | 0.083 | 60,000 | 58.7 | D | x |
| E17 | N-methyl- | 100 | 0.093 | 60,000 | 4.35 | A | — |
| | 2- | | | | | | |
| | pyrrolidone | | | | | | |
| E18 | pure water | 70 | 17.5 | 20.000 | 2.56 | A | — |
| | E. G. | 20 | 0.083 | | | | |
| | methanol | 10 | 97.3 | | | | |
| E19 | toluene | 100 | 21.8 | 20,000 | 1.29 | B | O |
| E20 | toluene | 100 | 21.8 | 60,000 | 2.38 | B | O |
| E21 | toluene | 100 | 21.8 | 100,000 | 4.16 | B | O |
| E22 | toluene | 100 | 21.8 | 400,000 | 3.88 | B | O |
| CE3 | toluene | 100 | 21.8 | 600,000 | 3.79 | E | x |
| E23 | toluene | 100 | 21.8 | 60,000 | 13.7 | D | O |
| E24 | toluene | 100 | 21.8 | 60,000 | 1.32 | B | O |
| E25 | o-di C. B. | 100 | 1.00 | 60,000 | 48.3 | D | O |
| E26 | T. C. P. | 100 | 2.38 | 60,000 | 34.4 | D | x |
| E27 | toluene | 60 | 21.8 | 100,000 | 5.63 | A | — |
| | o-di C. B. | 40 | 1.00 | | | | |
| E28 | pure water | 70 | 17.5 | 60,000 | 3.22 | A | — |
| | E. G. | 20 | 0.083 | | | | |
| | methanol | 10 | 97.3 | | | | |

E: Example
CE: Comparative Example
E.G.: Ethylene glycol,
o-di C. B: o-dichlorobenzene
T. C. P.: Trichloropropane

### Preparation of Organic LED Display

### Example 29

An ITO film of a glass substrate having formed thereon the 130 nm thick ITO film was worked to form ITO transparent stripe electrodes (1st electrode: positive electrode) of 220 μm in width having a pitch of 200 μm by photolithography method.

Then, the glass substrate was subjected to an ultrasonic washing using isopropyl alcohol, acetone and pure water for 10 minutes each, and then a UV ozone treatment and an O₂ plasma treatment were applied for 10 minutes each.

Then, using a solution formed by dissolving (triphenylamine-carbonate) copolymer (hereinafter, is referred to as Poly-TPD) shown by following structural formula (5) and tris(4-bromophenyl)aluminum-hexachloro-antimonate of 85:15 by weight ratio in dichloroethane, a layer of 100 nm was formed by spin coating.

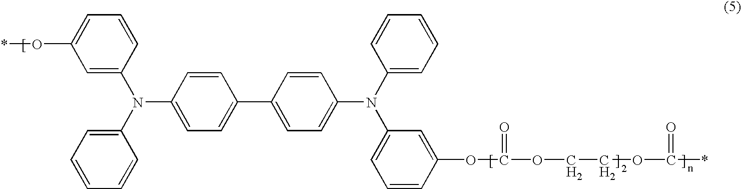

Then, by an inkjet printing apparatus, light-emitting materials each emitting a red light, a green light or a blue light respectively were patterning-coated on the electrode in stripe-form to form organic light-emitting layers each having a thickness of 100 nm. In this case, for the coating liquid for forming each organic light-emitting layer, the above-described MEH-CN-PPV of Example 27 was used for the organic red-light-emitting layer, the above-described Pre-PPV of Example 9 was used for the organic green-light-emitting layer, and the above-described PPP-NEt₃⁺ of Example 18 was used for the organic blue-light-emitting layer. However, in the case of forming the organic light-emitting layers, after first forming the film of Pre-PPV, the Pre-PPV was converted to PPV by applying a heat treatment to the film under an Ar atmosphere at 150° C. for 6 hours, and thereafter, the organic red-light-emitting layer and the organic blue-light-emitting layer were formed.

Then, an LiF film was formed on the whole surface at a thickness of 0.9 nm by a vapor deposition method, and Al electrodes (2nd electrode: negative electrode) of 0.2 μm in thickness and 300 μm in width and having a pitch of 320 μm were formed thereon by a vapor deposition method using a shadow mask.

Finally, by sealing using an epoxy resin, an organic LED display composed of plural organic LED devices was accomplished.

In the organic LED display prepared as described above, the occurrence of short-circuits between the positive electrode and the negative electrode, between positive electrodes each other, and between negative electrodes each other was not observed. Also, by applying a pulse voltage of 40 volts to the organic LED display thus prepared, emitted lights of red, green, and blue were observed.

### Example 30

An ITO film of a glass substrate having formed thereon the 130 nm thick ITO film was worked to form ITO transparent stripe electrodes (1st electrode: positive electrode) of 220 μm in width having a pitch of 200 μm by a photolithographic method.

Then, the glass substrate was washed by the same method as in Example 29 described above.

Then, partitions of 40 μm in width and 5 μm in thickness having a pitch of 220 μm were formed in the direction parallel to the electrodes and partitions of 40 μm in width and 5 μm in thickness having a pitch of 320 μm were formed in the direction crossing at right angle to the electrodes by a photoresist method using a positive-working photoresist.

Then, by an inkjet printing apparatus, positive hole transport layers were formed by using a coating liquid containing Pre-PPV of Example 9 at a thickness of 100 nm, and organic red-light-emitting layers were formed by coating thereon a coating liquid containing MEH-CH-PPV of Example 27 at a thickness of 100 nm, thereby red-light-emitting pixels were formed.

Then, by an inkjet printing apparatus, positive hole transport layers were formed by using a coating liquid containing PEDT of Example 28 at a thickness of 100 nm, and organic green-light-emitting layers were formed by coating thereon a coating liquid containing Pre-PPV of Example 9 at a thickness of 100 nm, thereby green light-emitting pixels were formed.

Then, by an inkjet-printing apparatus, blue-light-emitting pixels were formed at a thickness of 100 nm as an organic blue-light-emitting layer using a coating liquid containing PPP-Net₃⁺ of Example 18.

Then, an LiF film was formed on the whole surface thereof at a thickness of 0.9 nm by a vapor deposition method, and Al electrodes (2nd electrode: negative electrode) of 0.2 μm in thickness and 300 μm in width and having a pitch of 320 μm were formed thereon by a vapor deposition method using a shadow mask.

Finally, by sealing using an epoxy resin, an organic LED display composed of plural organic LED devices was accomplished.

In the organic LED display prepared as described above, the occurrence of short-circuits between the positive electrode and the negative electrode, between positive electrodes each other, and between negative electrodes each other was not observed. Also, by applying a pulse voltage of 40 volts to the organic LED display thus prepared, emitted lights of red, green, and blue were observed.

### Example 31

After forming a thin-film transistor on a glass substrate, a layer made of ITO was laminated thereon.

Then, by patterning the layer made of ITO to form 1st electrodes (positive electrode) and partitions were formed between the positive electrodes as Example 30.

Then, by the same manner as Example 30, organic LED devices were formed.

Then, an LiF film was formed on the whole surface at a thickness of 0.9 nm by a vapor deposition method, and Al electrodes (2nd electrode: negative electrode) were formed thereon at a thickness of 0.2 μm by a vapor deposition method.

Finally, by sealing using an epoxy resin, an organic LED display composed of plural organic LED devices was accomplished.

By applying a D.C. voltage of 5 volts to the organic LED display thus prepared, emitted lights of red, green, and blue were observed.

As described above, according to the coating liquid for forming an organic LED layer of the present invention, containing at least a solvent and an organic material, wherein the weight average molecular weight of the organic material is less than 600,000, the viscosity of the coating liquid at 20° C. is preferably 10 mPa·s or lower, and the coating liquid preferably contains at least a solvent having a vapor pressure at 20° C. of 10 mm Hg or lower, when the coating liquid is filled in the head of an inkjet printer and discharged, the occurrence of clogging of the head can be prevented and organic LED devices can be continuously and stably manufactured.

1-13. (Canceled)

14. A coating liquid discharging ink-jet nozzle comprising a coating liquid for forming an organic LED layer of an organic LED device by an ink-jet method, said coating liquid comprising a solvent or solvent mixture, and an organic material having a weight-average molecular weight of less than 600,000, said solvent or solvent mixture comprising at least one solvent component having a vapor pressure of 10 mmHg or less at 20° C.

15. A nozzle of claim 14, wherein the weight average molecular weight of said organic material is within the range of 20,000 to 100,000.

16. The nozzle of claim 14, wherein the coating liquid has a viscosity of 62 mPa·s or less at 20° C.

17. The nozzle of claim 16, wherein the viscosity is 10 mPa·s or less at 20° C.

18. The nozzle of claim 17, wherein the viscosity is within the range of 2 to 6 mPa·s at 20° C.

19. The nozzle of claim 14, wherein the at least one solvent component is selected from the group consisting of ethylene glycol, N-methyl-2-pyrrolidone, o-dichlorobenzene and trichloropropane.

20. The nozzle of claim 14, wherein the solvent or solvent mixture comprises water, methanol or toluene.

21. The nozzle of claim 14, wherein the at least one solvent component is a polyhydric alcohol, an amide or an aliphatic hydrocarbon.

22. The nozzle of claim 14, wherein the at least one solvent component is selected from the group consisting of ethylene glycol, propylene glycol, triethylene glycol, ethylene glycol monomethyl ether, ethylene glycol monoethyl ether, triethylene glycol monomethyl ether, triethylene glycol monoethyl ether, glycerin, formamide, N-methyl-2-pyrrolidone, nonane, decane, trichloropropane and o-dichlorobenzene.

23. A LED ink-jet printing partition comprising a coating liquid for forming an organic LED layer of an organic LED device by an ink-jet method, said coating liquid comprising a solvent or solvent mixture, and an organic material having a weight-average molecular weight of less than 600,000, said solvent or solvent mixture comprising at least one solvent component having a vapor pressure of 10 mmHg or less at 20° C.

24. A partition of claim 23, wherein the weight average molecular weight of said organic material is within the range of 20,000 to 100,000.

25. The partition of claim 23, wherein the coating liquid has a viscosity of 62 mPa·s or less at 20° C.

26. The partition of claim 25, wherein the viscosity is 10 mPa·s or less at 20° C.

27. The partition of claim 26, wherein the viscosity is within the range of 2 to 6 mPa·s at 20° C.

28. The partition of claim 23, wherein the at least one solvent component is selected from the group consisting of ethylene glycol, N-methyl-2-pyrrolidone, o-dichlorobenzene and trichloropropane.

29. The nozzle of claim 23, wherein the solvent or solvent mixture comprises water, methanol or toluene.

30. The nozzle of claim 23, wherein the at least one solvent component is a polyhydric alcohol, an amide or an aliphatic hydrocarbon.

31. The nozzle of claim 23, wherein the at least one solvent component is selected from the group consisting of ethylene glycol, propylene glycol, triethylene glycol, ethylene glycol monomethyl ether, ethylene glycol monoethyl ether, triethylene glycol monomethyl ether, triethylene glycol monoethyl ether, glycerin, formamide, N-methyl-2-pyrrolidone, nonane, decane, trichloropropane and o-dichlorobenzene.
